(19) United States
(12) Patent Application Publication
(10) Pub. No.: US 2025/0318406 A1
(43) Pub. Date: Oct. 9, 2025

(54) DISPLAY DEVICE AND ELECTRONIC DEVICE

(71) Applicant: SAMSUNG DISPLAY CO., LTD., YONGIN-SI (KR)

(72) Inventors: Wan-Sang KIM, Yongin-si (KR); Yongil KIM, Yongin-si (KR); Byoungkyoo PARK, Yongin-si (KR); Wee-Joon JEONG, Yongin-si (KR); Jang Un CHOI, Yongin-si (KR)

(21) Appl. No.: 19/016,235

(22) Filed: Jan. 10, 2025

(30) Foreign Application Priority Data
Apr. 9, 2024 (KR) 10-2024-0048066

(51) Int. Cl. H10K 59/80; H10K 50/19; H10K 59/121; H10K 59/38

(52) U.S. Cl. CPC H10K 59/873; H10K 50/19; H10K 59/1213; H10K 59/38; H10K 59/871; H10K 59/8792

(57) ABSTRACT

A display device according to an embodiment includes a tempered glass plate, a first display portion located on an upper portion of the tempered glass plate and including a pixel circuit layer and a light emitting element layer, and a transmission area arranged in one direction, a second display unit located below the tempered glass plate in an opposite direction to the first display unit and having a display area including a pixel circuit layer and a light emitting element layer and a transmission area arranged in one direction.

### CROSS-REFERENCE TO RELATED APPLICATION

This application claims priority to and the benefit of Korean Patent Application No. 10-2024-0048066 filed at the Korean Intellectual Property Office on Apr. 9, 2024, the entire contents of which are incorporated by reference herein.

### BACKGROUND

### 1. Technical Field

One or more embodiments described herein relate to a display device and electronic device.

### 2. Description of the Related Art

Light emitting devices have various advantages such as wide viewing angle, fast response speed, thinness, and low power consumption. As a result, they are widely applied to various electrical and electronic devices such as televisions, monitors, and mobile phones.

One type of light emitting device is an organic light emitting diode (OLED). An OLED is a self-emitting device where holes injected from an anode and electrons injected from a cathode combine in an emitting layer to form excitons. When the excitons stabilize, light is emitted.

In order to implement a highly efficient display device, a display device including a color conversion layer has been proposed. The color conversion layer may convert incident light into different colors. Recently, transparent displays have been developed in which both the anode and cathode of an organic light emitting display device are made of transparent electrodes, and the driving thin film transistor is made of an optically transparent material.

### SUMMARY

One or more embodiments provide a bidirectional display device which not only displays images in one direction, but also displays images in another direction, allowing opposing sides of the display device to be utilized.

One or more additional embodiments provide a transparent display device, where the light reflected from an object located behind the transmission area is transmitted to the front side of the display device, thereby allowing the object behind to be seen from the front of the display device.

A display device according to an embodiment includes a tempered glass plate, a first display unit located on an upper portion of the tempered glass plate and including a first display area which includes a first pixel circuit layer and a first light emitting element layer, and a first transmission area arranged in one direction, and a second display unit located below the tempered glass plate in an opposite direction to a first display and having a second display area including a second pixel circuit layer and a second light emitting element layer and a second transmission area arranged in one direction.

In the display device, each of the first display area of the first display unit and the second display area of the second display unit includes unit pixel rows containing red, green, and blue colors, when viewed from the front of the first display unit. Unit pixel rows of the first display area of the first display unit and the second display area of the second display unit may overlap in one direction.

In the display device, each of the first and second display areas of the first display unit and the second display unit includes a row of unit pixels containing one red pixel, one green pixel, and one blue pixel, when viewed from the front of the first display unit, the rows of unit pixels in the first and second display areas of the first and second display units may not overlap in one direction.

In the display device, the first display area of the first display unit and the second display area of the second display unit have the first and second transmission areas located between adjacent pixel rows that emit light of different colors, respectively, when viewed from the front of the first display unit. When viewed, pixel rows of the first display area of the first display unit and the second display area of the second display unit may overlap in one direction.

In the display device, the first display area of the first display unit and the second display area of the second display unit have the first and second transmission areas located between adjacent pixel rows that emit light of different colors, respectively, when viewed from the front of the first display unit. When viewed, the pixel rows of the first display area of the first display unit and the second display area of the second display unit may not overlap in one direction.

In the display device, each of the first light emitting element layer and the second light emitting element layer may include a blue light emitting layer.

In the display device, the first display unit may include a first thin film encapsulation layer on an upper portion of the first light emitting element layer of the first display portion, and the second display portion may include a second thin film encapsulation layer on a lower portion of the second light emitting element layer of the second display portion.

In the display device, each of the first thin film encapsulation layer and the second thin film encapsulation layer may include a triple layer in which an inorganic layer, an organic layer, and an inorganic layer are sequentially formed.

In the display device, the first display unit may include a first color conversion layer above the first thin film encapsulation layer of the first display unit, and the second display unit may include a second color conversion layer below the second thin film encapsulation layer of the second display unit.

In the display device, each of the first color conversion layer and the second color conversion layer may include quantum dots QD.

In the display device, the first display unit may include a first color filter layer above the first color conversion layer of the first display unit, and the second display unit may include a second color filter layer below the second color conversion layer of the second display unit.

In the display device, the first display unit may include a first cover glass substrate above the first color filter layer of the first display unit, and the second display unit may include a second cover glass substrate below the second color filter layer of the second display unit.

In the display device, the first display unit may include a first anti-reflection film on an upper portion of a first cover glass substrate of the first display unit, and the second display unit may include a second anti-reflective film on a lower portion of the second cover glass substrate of the second display unit.

In the display device, the first display unit may further include a first overcoat layer above the first color filter layer of the first display unit, and the second display unit may include a second overcoat layer below the second color filter layer of the second display unit.

The display device includes a pixel circuit sublayer which may include an oxide thin film transistor.

In the display device, a semiconductor layer of the oxide thin film transistor may include ITO (indium tin oxide), poly-ITO, IZO (indium zinc oxide), IGZO (indium gallium zinc oxide), and ITZO (indium tin zinc oxide).

A display device according to one embodiment includes the first display unit and a second display unit located on opposing sides of the tempered glass plate, a printed circuit board, a first integrated circuit film connecting the first display unit and the printed circuit board, a second integrated circuit film connecting the second display unit and the printed circuit board, and drive chips formed on the first integrated circuit film and the second integrated circuit film, wherein the first integrated circuit film may be connected to a first side of the printed circuit board and said second integrated circuit film may be connected to a second side of the printed circuit board.

In the display device, the first side and the second side may be the same side of the printed circuit board.

In the display device, the second integrated circuit film may include a via hole penetrating the second integrated circuit film and a via pattern formed in the via hole.

In the display device, the second side may be the other side of the printed circuit board located on the opposite side of the first side.

According to embodiments, the display device is a transparent display, and light reflected from an object behind in the transmission area is transmitted to the front, allowing the object behind the display device to be viewed from the front of the display device. In addition, bidirectional information may be transmitted by providing a bidirectional display, and by sharing the tempered glass plate, material costs of existing glass substrates may be reduced. In addition, other features and advantages of the present disclosure may be newly understood through embodiments of the present disclosure.

According to embodiments, An electronic device comprising a memory, a processor executing an application stored in the memory, and a display device comprising a display module outputting video information provided by the application, wherein the display device comprising a tempered glass plate, a first display located on a first side of the tempered glass plate and having a first display area and a first transmission area arranged in one direction, the display area including a first pixel circuit layer and a first light emitting element layer, and a second display located on a second side of the tempered glass plate in an opposite direction to the first side which the first display is located on, the second display having a second display area including a second pixel circuit layer and a second light emitting element layer and a second transmission area arranged in the one direction.

### BRIEF DESCRIPTION OF THE DRAWINGS

FIG. 1 is a cross-sectional view of a display device according to an embodiment of the present disclosure.

FIG. 2 is a cross-sectional view of a first display unit of the display device of FIG. 1 according to an embodiment.

FIG. 3 is a cross-sectional view of a display device according to another embodiment of the present disclosure.

FIG. 4 and FIG. 5 are plan views showing an example of a display device.

FIG. 6 and FIG. 7 are plan views showing an example of a display device.

FIG. 8 and FIG. 9 are plan views showing an example of a display device.

FIG. 10 and FIG. 11 are plan views showing an example of a display device.

FIG. 12 is a perspective view of a display device according to an embodiment.

FIG. 13 is a perspective view of a display device according to another embodiment.

FIG. 14 is a cross-sectional view of one embodiment of FIG. 12.

FIG. 15 is a cross-sectional view of another embodiment of FIG. 13.

FIG. 16 is a cross-sectional view of the second integrated circuit film of FIG. 14 according to an embodiment.

FIG. 17 is a cross-sectional view of the printed circuit board of FIG. 14 according to an embodiment.

FIG. 18 is a block diagram of an electronic device according to some embodiments.

FIG. 19 shows schematic diagrams of electronic devices according to various embodiments.

### DETAILED DESCRIPTION

Hereinafter, with reference to the attached drawings, various embodiments of the present disclosure will be described in detail so that those skilled in the art may easily implement the present disclosure. The invention may be implemented in many different forms and is not limited to the embodiments described herein.

The size and thickness of each component shown in the drawings are arbitrarily shown for convenience of explanation, so the present disclosure is not necessarily limited to that which is shown. In the drawing, the thickness is enlarged to clearly express various layers and areas. And in the drawings, for convenience of explanation, the thicknesses of some layers and regions are exaggerated.

Additionally, when a part of a layer, membrane, region, or plate is said to be “above” or “on” another part, this includes not only cases where it is “directly above” another part, but also cases where there is another part in between. In contrast, when an element is referred to as being “directly on” another element, there are no intervening elements present. In addition, being “above” or “on” a reference part means being located above or below the reference part, and does not necessarily mean being located “above” or “on” it in the direction opposite to gravity.

Additionally, throughout the specification, when it is said that a part “includes” a certain component, this means that it may further include other components rather than excluding other components, unless specifically stated to the contrary.

In addition, throughout the specification, when reference is made to “on a plane,” this means when the target part is viewed from above, and when reference is made to “in a cross-section,” this means when a cross-section of the target portion is cut vertically and viewed from the side.

In addition, throughout the specification, when “connected” is used, it does not only mean that two or more components are directly connected, but also includes cases where two or more components are indirectly connected through another component, physically connected, or electrically connected, as well as cases where parts that are essentially integrated but referred to by different names according to their position or function are connected to each other.

In addition, throughout the specification, when a part such as a conductor, layer, film, region, plate, or component is said to “extend in the first or second direction,” this does not only mean a straight shape extending in that direction, rather, it is a structure that extends overall along the first or second direction, and also includes a structure that is bent at some part, has a zigzag structure, or extends while including a curved structure.

Additionally, electronic devices that include display devices and display panels described in the specification (for example, mobile phones, TVs, monitors, laptop computers, etc.) or electronic devices that include display devices and display panels manufactured by the manufacturing method described in the specification are also not excluded from the scope of rights of this specification.

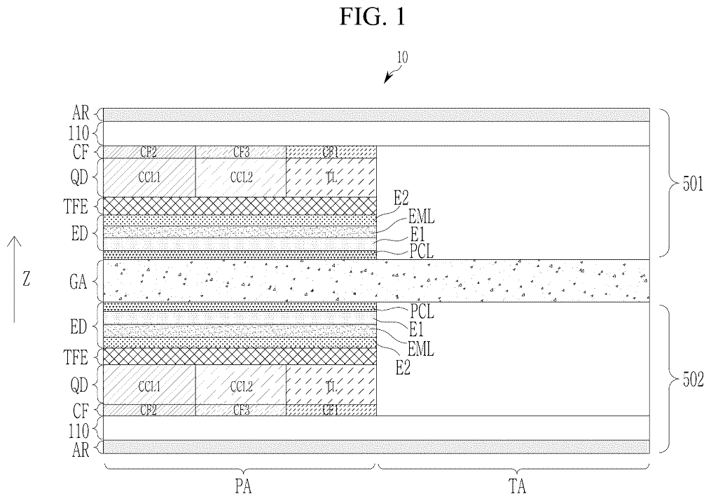

Hereinafter, a display device according to an embodiment will be described with reference to FIG. 1.

FIG. 1 is a cross-sectional view of a display device 10 equipped with a plurality of display units according to an embodiment. In this embodiment, the display device 10 of FIG. 1 includes a first display unit 501, a second display unit 502, a tempered glass plate GA, a cover glass substrate 110, and an anti-reflection film AR. The first display unit 501 and the second display unit 502 may be divided into a display area PA and a transmission area TA, respectively, each having predetermined widths. In FIG. 1, the widths of display area PA and transmission area TA appear to be substantially the same but the widths may be different in other embodiments. The display area PA displays images or information, and the transmission area TA allows light reflected from an object behind the display device to be transmitted to the front of the display device. This allows objects behind the display to be visible from the front of the display device. The transmission area TA may include the tempered glass plate GA and a cover glass substrate 110, and may additionally have a transparent insulating layer. The transmission area TA is located between adjacent display areas PA to form a transparent display device.

As shown in FIG. 1, the first display unit 501 and the second display unit 502 may share one tempered glass plate GA. More specifically, the first display unit 501 may be formed on one side of the tempered glass plate GA, and the second display portion 502 may be formed on the other side of the tempered glass plate GA. The first display unit 501 and the second display unit 502 may have one or more similar layers.

A pixel circuit layer PCL may be located in the display area PA of the first display unit 501 in the z-axis direction of the tempered glass plate GA (hereinafter referred to as the top). The pixel circuit layer PCL may include one or more thin film transistors. In one embodiment, the layer where the thin film transistor(s) are located may be referred to as the pixel circuit layer PCL.

In order to implement a transparent display, each thin film transistor may be implemented as an oxide thin film transistor. The oxide thin film transistor may include a gate electrode and a semiconductor layer, and the semiconductor layer may be formed of an oxide semiconductor material. Examples of oxide semiconductor materials include Indium Tin Oxide ITO, poly-ITO, Indium Zinc Oxide IZO, indium gallium zinc oxide IGZO, and indium tin zinc oxide ITZO.

A light emitting element layer ED may be located on top of the pixel circuit layer PCL. The light emitting element layer ED includes a first electrode E1, a light emitting layer EML, and a second electrode E2. The first electrode E1 may be an anode, which is a hole injection electrode. A light emitting layer EML may be located on top of the first electrode E1. In one embodiment, the light emitting layer EML may be a color (e.g., blue) light emitting layer BLUE OLED and a 4 tandem structure may be applied. The 4 tandem structure is a structure in which four light emitting layers are stacked, and may improve the brightness and lifespan of the display. Additionally, structures other than the 4 tandem structure may also be used. The second electrode E2 may be located on the light emitting layer EML. The second electrode E2 may be a cathode, which is an electron injection electrode.

A thin film encapsulation layer TFE may be located on the second electrode E2. The thin film encapsulation layer TFE may protect the light emitting elements inside the display from exposure to moisture and oxygen and may extend its lifespan. The thin film encapsulation layer TFE may include a plurality of layers, and may be formed as a composite layer including both an inorganic layer and an organic layer. The composite membrane may be sequentially composed of an inorganic layer, an organic layer, and an inorganic layer.

A color conversion layer may be located on top of the thin film encapsulation layer TFE. QD (Quantum Dot) may be used as the color conversion layer. The color conversion layer may be composed of a first color conversion layer CCL1, a second color conversion layer CCL2, and a transmission layer TL. The first color conversion layer CCL1 converts incident light into red light to be emitted. The second color conversion layer CCL2 converts incident light into green light to be emitted. However, light incident on the transmission layer TL is transmitted without color conversion. The incident light may include blue light emitted from the light emitting layer EML. The incident light may be blue light alone or a mixture of blue light and green light. Alternatively, the incident light may include all of blue light, green light, and red light, e.g., white light.

A color filter layer CF may be located on the color conversion layer. The color filter layer CF may include a first color filter CF1, a second color filter CF2, and a third color filter CF3. The first color filter CF1 may overlap the transmission layer TL. The first color filter CF1 may transmit blue light that has passed through the transmission layer TL and may absorb light of the remaining wavelengths, thereby increasing the purity of blue light emitted from the display device.

The second color filter CF2 may overlap the first color conversion layer CCL1. The second color filter CF2 may transmit red light that has passed through the first color conversion layer CCL1 and absorb light of the remaining wavelengths, thereby increasing the purity of red light emitted from the display device.

The third color filter CF3 may overlap the second color conversion layer CCL2. The third color filter CF3 may transmit green light that has passed through the second color conversion layer CCL2 and absorb light of the remaining wavelengths, thereby increasing the purity of green light emitted from the display device.

A cover glass substrate 110 may be located on the color filter layer. The cover glass substrate 110 performs the function of protecting the front of the display device and may serves as a cover window. The top of the cover glass substrate 110 may be coated with an anti-reflective film AR. The anti-reflection film AR may reduce light incident from the outside and may make the light coming from inside the panel clearer.

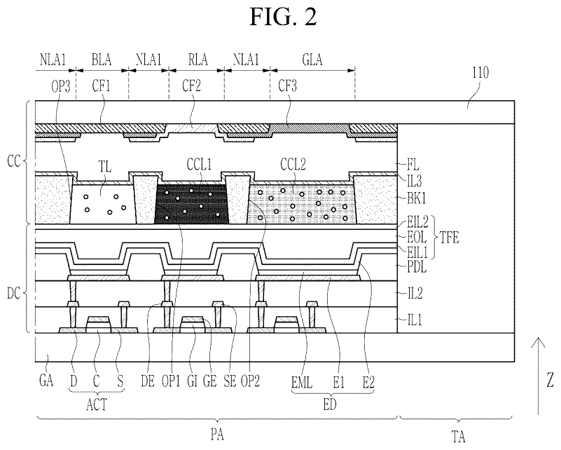

In one embodiment, the first display unit 501 and the second display unit 502 may have the same structure and may be formed on the upper and lower sides of the tempered glass plate GA, respectively. The directions in which the first display unit 501 and the second display unit 502 are stacked may be opposite to each other relative to the z-axis direction. The structure of the first display unit 501 according to the embodiment of FIG. 1 will be explained in greater detail with reference to FIG. 2.

FIG. 2 is a cross-sectional view of the first display unit 501 according to the embodiment of FIG. 1. The first display unit 501 may be divided into a color conversion part CC and a pixel unit DC. Additionally, the first display unit 501 may be divided into a display area PA and a transmission area TA in a direction crossing direction Z. The display area PA according to one embodiment includes a red light emitting region RLA, a green light emitting region GLA, and a blue light emitting region BLA. A non-light emitting region (NLA1) may be located between adjacent pairs of the red light emitting region RLA, the green light emitting region GLA, and the blue light emitting region BLA. Each light emitting region may correspond to a pixel. For example, the blue light emitting region BLA, red light emitting region RLA, and green light emitting region GLA may correspond to blue pixels, red pixels, and green pixels, respectively.

The cross-sectional structure of the display area PA will now be explained in greater detail. The pixel unit DC according to one embodiment includes a plurality of driving transistors, one for each pixel. Each driving transistor includes a semiconductor layer ACT and a gate electrode GE, a light emitting element layer ED, and a thin film encapsulation layer TFE. A tempered glass plate GA provides transparency and excellent durability to protect against physical damage.

The semiconductor layer ACT is located at the top (hereinafter referred to as top) in the z-axis direction of the tempered glass plate GA. The semiconductor layer ACT may include an oxide semiconductor. The semiconductor layer ACT includes a channel region C, a source region S, and a drain region D. The source region S and drain region D are arranged on respective sides of the channel region C.

An interlayer insulating layer IL1 is located on the gate electrodes GE and the gate insulating layers GI of the driving transistors. Openings exposing the source region S and drain region D are located in the interlayer insulating layer IL1. A source electrode SE and a drain electrode DE are located on the interlayer insulating layer IL1. The source electrode SE and drain electrode DE are respectively connected to the source region S and drain region D of the semiconductor layer ACT through openings formed in the interlayer insulating layer IL1.

A protective layer IL2 is located on the interlayer insulating layer IL1, the source electrode SE, and the drain electrode DE. A first electrode E1 is located on the protective layer IL2. The first electrode E1 is connected to the drain electrode DE through an opening in the protective layer IL2.

A corresponding one of the driving transistors including the gate electrode GE, the semiconductor layer ACT, the source electrode SE, and the drain electrode DE is connected to the first electrode E1 and supplies driving current to the light emitting element layer ED.

A pixel defining layer PDL is located on top of the protective layer IL2 and the first electrode E1. The pixel defining layer PDL overlaps the first electrode E1 and may have an opening that defines the light emitting region of the pixel. The light emitting layer EML is located on the first electrode E1 at a location overlapping the pixel opening. Each light emitting layer EML may be include a color light emitting layer, e.g., a blue light emitting layer BLUE OLED. In addition, the light emitting layer EML may be a multi-layer that further includes one or more of a hole injection layer HIL, a hole transporting layer HTL, an electron transporting layer ETL, and an electron injection layer EIL. The light emitting layer EML may be located mostly within the pixel opening, and may also be located on the side or top of the pixel defining layer PDL.

The second electrode E2 is located on the light emitting layer EML. The second electrode E2 may be located across the plurality of pixels and may receive a common voltage through a common voltage transmitter in the non-display area.

The first electrode E1, the light emitting layer EML, and the second electrode E2 may form the light emitting element layer ED for a corresponding one of the pixels. Here, the first electrode E1 may be an anode (which is a hole injection electrode) and the second electrode E2 may be a cathode, which is an electron injection electrode. However, the embodiment is not necessarily limited to this, and the first electrode E1 may be a cathode and the second electrode E2 may be an anode depending on the driving method of the organic light emitting display device.

In operation, holes and electrons are injected into the light emitting layer EML from the first electrode E1 and the second electrode E2, respectively. Light emission occurs when excitons formed when the injected holes and electrons combine fall from the excited state to the ground state.

A thin film encapsulation layer TFE is located on the second electrode E2. The thin film encapsulation layer TFE may seal the display layer by covering not only the top surface, but also the side surfaces, of the display layer including the light emitting element layer ED. Since light emitting devices are very vulnerable to moisture and oxygen, the thin film encapsulation layer TFE seals the display layer and blocks inflow of external moisture and oxygen. In one embodiment, the thin film encapsulation layer TFE may include multiple layers and may be formed as a composite layer that includes both inorganic and organic layers. In one embodiment, the thin film encapsulation layer TFE may be formed as a triple layer, with the first inorganic layer EIL1, organic layer EOL, and second inorganic layer EIL2 sequentially formed.

The color conversion part CC is located on top of the thin film encapsulation layer TFE. The color conversion part CC includes the cover glass substrate 110 that overlaps the tempered glass plate GA. The color conversion part CC may include a bank BK1 located on the thin film encapsulation layer TFE. The bank BK1 may include a first opening OP1, a second opening OP2, and a third opening OP3 that overlap the pixel openings. The sizes of the first opening OP1, the second opening OP2, and the third opening OP3 may be different or the same.

The first color conversion layer CCL1 may be located within the first opening OP1. The first color conversion layer CCL1 may convert supplied light into red light. The first color conversion layer CCL1 may include quantum dots. The second color conversion layer CCL2 may be located within the second opening OP2. The second color conversion layer CCL2 may convert supplied light into green light. The second color conversion layer CCL2 may include quantum dots. In one embodiment, the color conversion layers and transmission layer TL in FIG. 2 may be provided in the same order as shown in FIG. 1. Now, the quantum dots in the color conversion layers will be described in detail below.

The quantum dots (hereinafter, also referred to as semiconductor nanocrystals) may include Group II-VI compounds, Group III-V compounds, Group IV-VI compounds, Group IV elements or compounds, Group I-III-VI compounds, Group II-III-VI compounds, Group I-II-IV-VI compounds, or combinations thereof.

The Group II-VI compounds include binary compounds selected from the group consisting of CdSe, CdTe, ZnS, ZnSe, ZnTe, ZnO, HgS, HgSe, HgTe, MgSe, MgS, and mixtures thereof; a group made up of a tri-element compound selected from AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS; and mixtures thereof; and a tetraelement compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof. The group II-VI compound may further include a Group III metal.

The Group III-V compounds are binary compounds selected from the group consisting of GaN, GaP, GaAs, GaSb, AlN, AlP, AlAs, AlSb, InN, InP, InAs, InSb, and mixtures thereof; A ternary compound selected from the group consisting of GaNP, GaNAs, GaNSb, GaPAs, GaPSb, AlNP, AlNAs, AlNSb, AlPAs, AlPSb, InGaP, InNP, InNAs, InNSb, InPAs, InZnP, InPSb, and mixtures thereof; and a quaternary compound selected from the group consisting of GaAINP, GaAINAs, GaAINSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and mixtures thereof. The Group III-V compound may further include a group II metal (e.g., InZnP).

The Group IV-VI compounds include binary compounds selected from the group consisting of SnS, SnSe, SnTe, PbS, PbSe, PbTe, and mixtures thereof; a ternary compound selected from the group consisting of SnSeS, SnSeTe, SnSTe, PbSeS, PbSeTe, PbSTe, SnPbS, SnPbSe, SnPbTe, and mixtures thereof; and a quaternary element compound selected from the group consisting of SnPbSSe, SnPbSeTe, SnPbSTe, and mixtures thereof.

The Group IV element or compound is a monoelement compound selected from the group consisting of Si, Ge, and combinations thereof, and a binary compound selected from the group consisting of SiC, SiGe, and combinations thereof, but is not limited thereto.

Examples of the Group I-III-VI compounds include, but are not limited to, CuInSe2, CuInS2, CuInGaSe, and CuInGaS. Examples of the Group I-II-IV-VI compounds include, but are not limited to, CuZnSnSe, and CuZnSnS. The Group IV element or compound is a single element selected from the group consisting of Si, Ge, and mixtures thereof, and a binary compound selected from the group consisting of SiC, SiGe, and mixtures thereof.

The Group II-III-VI compound may be selected from the group consisting of ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe, HgInTe, MgGaS, MgAlS, MgInS, MgGaSe, MgAlSe, MgInSe, and combinations thereof, but is not limited to thereto.

The Group I-II-IV-VI compound may be selected from CuZnSnSe and CuZnSnS, but is not limited thereto.

In one embodiment, the quantum dots may not include cadmium. Quantum dots may include semiconductor nanocrystals based on Group III-V compounds including indium and phosphorus. The Group III-V compound may further include zinc. Quantum dots may include semiconductor nanocrystals based on Group II-VI compounds including chalcogen elements (e.g., sulfur, selenium, tellurium, or combinations thereof) and zinc.

In quantum dots, the above-mentioned di-element compound, tri-element compound, and/or quaternary compound may exist in the particle at a uniform concentration, or may exist in the same particle with the concentration distribution partially divided into different states. Additionally, one quantum dot may have a core/shell structure surrounding other quantum dots. The interface between the core and the shell may have a concentration gradient in which the concentration of elements present in the shell decreases toward the center.

In some embodiments, quantum dots may have a core-shell structure including a core containing the above-described nanocrystals and a shell surrounding the core. The shell of the quantum dot may serve as a protective layer to maintain semiconductor properties by preventing chemical denaturation of the core and/or as a charging layer to impart electrophoretic properties to the quantum dot. The shell may be single or multi-layered. The interface between the core and the shell may have a concentration gradient in which the concentration of elements present in the shell decreases toward the center. Examples of the shell of the quantum dot include metal or non-metal oxides, semiconductor compounds, or combinations thereof.

For example, the oxide of the metal or non-metal is a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or MgAl₂O₄, CoFe₂O₄, NiFe₂O₄, CoMn₂O₄, etc., but the present disclosure is not limited thereto.

In addition, the semiconductor compounds include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc. However, the present disclosure is not limited thereto.

The interface between the core and the shell may have a concentration gradient in which the concentration of elements present in the shell decreases toward the center. Additionally, the semiconductor nanocrystal may have a structure including a single semiconductor nanocrystal core and a multi-layered shell surrounding it. In one embodiment, the multi-layer shell may have two or more layers, such as 2, 3, 4, 5, or more layers. The two adjacent layers of the shell may have a single composition or different compositions. In a multi-layer shell, each layer may have a composition that changes along a radius.

Quantum dots may have a full width at half maximum (FWHM) of the emission wavelength spectrum of about 45 nm or less, in one embodiment about 40 nm or less, and in one or more additional embodiments about 30 nm or less. Within this range, color purity or color reproducibility may be improved. Additionally, since the light emitted through these quantum dots is emitted in all directions, the optical viewing angle may be improved.

In one embodiment, the quantum dots may have different energy band gaps between the shell material and the core material. For example, the energy band gap of the shell material may be greater than that of the core material. In other embodiments, the energy band gap of the shell material may be less than that of the core material. The quantum dots may have a multi-layered shell. In a multi-layer shell, the energy band gap of the outer layer may be greater than that of the inner layer (e.g., the layer close to the core). In a multi-layer shell, the energy band gap of the outer layer may be less than that of the inner layer.

Quantum dots may control absorption/emission wavelengths by adjusting their composition and size. The maximum emission peak wavelength of the quantum dot may range from ultraviolet to infrared wavelengths or longer.

Quantum dots may have a predetermined quantum efficiency. For example, the quantum dots may have a quantum efficiency of at least about 10%, such as at least about 30%, at least about 50%, at least about 60%, at least about 70%, at least about 90%, or even 100%. Quantum dots may have a relatively narrow spectrum. The quantum dots may have a full width at half maximum of the emission wavelength spectrum of, for example, about 50 nm or less, in some embodiments about 45 nm or less, in some embodiments about 40 nm or less, or in still other embodiments about 30 nm or less.

The quantum dots may have a predetermined particle size. For example, the quantum dots may have a particle size that lies in the range of about 1 nm or more and about 100 nm or less. The size of a particle refers to the diameter of the particle or the diameter converted by assuming a spherical shape from a two-dimensional image, obtained, for example, by transmission electron microscopy analysis. In one embodiment, the quantum dots may have sizes ranging from about 1 nm to about 20 nm, for example, more than 2 nm, more than 3 nm, or more than 4 nm, and less than 50 nm, less than 40 nm, less than 30 nm, less than 20 nm, less than 15 nm, for example, less than 10 nm. The quantum dots may have a variety of shapes. For example, the shapes of the quantum dots may include, but is not limited to, a sphere, polyhedron, pyramid, multipod, square, cuboid, nanotube, nanorod, nanowire, nanosheet, or a combination thereof.

Quantum dots are commercially available or may be appropriately synthesized. The particle size of quantum dots may be controlled relatively freely during colloid synthesis, and the particle size may also be adjusted uniformly.

Quantum dots may include organic ligands (e.g., having hydrophobic and/or hydrophilic moieties). The organic ligand residue may be bound to the surface of the quantum dot. The organic ligand includes RCOOH, RNH₂, R₂NH, R₃N, RSH, R₃PO, R₃P, ROH, RCOOR, RPO(OH)₂, RHPOOH, R₂POOH, or combinations thereof, where R independently represents a substituted or unsubstituted alkyl, a substituted or unsubstituted alkenyl of C3 to C40 (for example, C5 or more and C24 or less), a substituted or unsubstituted aliphatic hydrocarbon group of C3 to C40, a substituted or unsubstituted aryl group of C6 to C40 (for example, C6 or more and C20 or less), a substituted or unsubstituted aromatic hydrocarbon group, or combinations thereof.

Examples of the organic ligands include thiol compounds such as methane thiol, ethane thiol, propane thiol, butane thiol, pentane thiol, hexane thiol, octane thiol, dodecane thiol, hexadecane thiol, octadecane thiol, and benzyl thiol; amines such as methane amine, ethane amine, propane amine, butane amine, pentyl amine, hexyl amine, octyl amine, nonylamine, decylamine, dodecyl amine, hexadecyl amine, octadecyl amine, dimethyl amine, diethyl amine, dipropyl amine, tributylamine, and trioctylamine; carboxylic acid compounds such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, and benzoic acid; phosphine compounds such as methyl phosphine, ethyl phosphine, propyl phosphine, butyl phosphine, pentyl phosphine, octyl phosphine, dioctyl phosphine, tributyl phosphine, and trioctyl phosphine; phosphine compounds or their oxide compounds such as methyl phosphine oxide, ethyl phosphine oxide, propyl phosphine oxide, butyl phosphine oxide, pentyl phosphine oxide, tributyl phosphine oxide, octyl phosphine oxide, dioctyl phosphine oxide, trioctyl phosphine oxide, diphenyl phosphine, and triphenyl phosphine compounds or their oxide compounds; alkylphosphinic acids such as hexylphosphinic acid, octylphosphinic acid, dodecylphosphinic acid, tetradecylphosphinic acid, hexadecylphosphinic acid, octadecylphosphinic acid, C5 to C20 alkyl phosphinic acids, and C5 to C20 alkyl phosphonic acids; however, but are not limited to, these. Quantum dots may include hydrophobic organic ligands alone or in a mixture of one or more types. The hydrophobic organic ligand may not contain a photopolymerizable residue (e.g., an acrylate group, a methacrylate group, etc.).

Referring again to FIG. 2, a color conversion insulating layer IL3 may be positioned on the bank BK1, the first color conversion layer CCL1, the second color conversion layer CCL2, and transmission layer TL. The color conversion insulating layer IL3 may have a shape that covers the bank BK1, the first color conversion layer CCL1, the second color conversion layer CCL2, and the transmission layer. According to one embodiment, the color conversion insulating layer IL3 may be omitted.

The interlayer insulating layer IL1, the protective layer IL2, and the color conversion insulating layer IL3 may be insulating films made of organic or inorganic materials. The inorganic insulating film may include a silicon oxide SiOₓ, a silicon nitride SiNₓ, or a silicon oxynitride SiOₓN_{y}. The organic insulating film may include one or more materials selected from the group consisting of polyimide, polyamide, acrylic resin, benzocyclobutene, and phenol resin.

According to one embodiment, the transmission layer TL may be located in the third opening OP3 of the bank BK1. Additionally, the transmission layer TL may be located in a portion corresponding to the blue light emitting region BLA in the space partitioned by the bank BK1. The transmission layer TL may transmit light incident from the light emitting element layer ED of the corresponding pixel that emits blue light. In the display panel according to this embodiment, the first color conversion layer CCL1 converts the incident light from a corresponding pixel into red light to be emitted. Additionally, the second color conversion layer CCL2 converts incident light from a corresponding pixel into green light to be emitted. However, the light incident on the transmission layer TL is transmitted without color conversion. In this case, the incident light may include blue light. The incident light may be blue light alone or a mixture of blue light and another color of light, e.g., green light. In one embodiment, the incident light may include all of blue light, green light, and red light, e.g., white light. As previously indicated, the order of the first color conversion layer CCL1, the second color conversion layer CCL2, and the transmission layer TL in FIG. 2 is different from the order of these layers in FIG. 1. In one embodiment, the order of the first color conversion layer CCL1, the second color conversion layer CCL2, and the transmission layer TL in FIG. 2 may be in the same order as indicated in FIG. 1.

A filling layer FL may be located on the color conversion insulating layer IL3. The filling layer FL may be located on and extend over the bank BK1, the first color conversion layer CCL1, the second color conversion layer CCL2, and the transmission layer TL. The color conversion part CC includes a first color filter CF1, a second color filter CF2, and a third color filter CF3 located between the cover glass substrate 110 and the pixel unit DC.

At least two of the third color filter CF3, second color filter CF2, and first color filter CF1 may overlap in the non-light emitting region NLA1 and serve as a light blocking layer. The non-light emitting region NLA1 may overlap the pixel definition layer PDL of the pixel unit DC and the bank BK1 of the color conversion part CC.

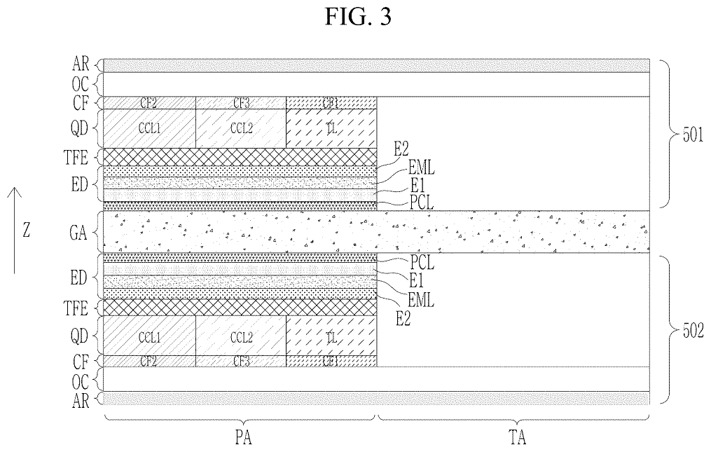

The transmission area TA includes the tempered glass plate GA and the cover glass substrate 110. In one embodiment, the transmission area TA may optionally include at least one layer of transparent insulating layers (for example, IL1, IL2, IL3, FL) through which light may transmit, and may not include layers that block light (for example, conductive layers such as gate electrodes, source/drain electrodes, etc.). In one embodiment, an overcoat layer OC may be positioned instead of the cover glass substrate 110. Hereinafter, a modified embodiment of the embodiment of FIG. 1 will be looked at through FIG. 3.

FIG. 3 is a cross-sectional view of a display device according to another embodiment of the present disclosure. In this embodiment, the overcoat layer OC is used instead of the cover glass substrate 110. Otherwise, the display device may have the same structure as the embodiment of FIG. 1 described above. The overcoat layer OC may cover the color filter layer CF and may be positioned on top of the color filter layer CF. The overcoat layer OC is intended to protect and planarize the top surface of the display device, may include an organic insulating material, and may be a single layer or multiple layers. The organic insulating material may include, for example, one or more materials selected from the group consisting of polyimide, polyamide, acrylic resin, benzocyclobutene, and phenolic resin.

The transmission area TA includes the tempered glass plate GA, and at least one layer of the transparent insulating layers (in one embodiment, OC, IL1, IL2, IL3, FL) through which light can pass. Layers that block light (for example, conductive layers such as gate electrodes, source/drain electrodes, etc.) may not be positioned in the transmission area TA.

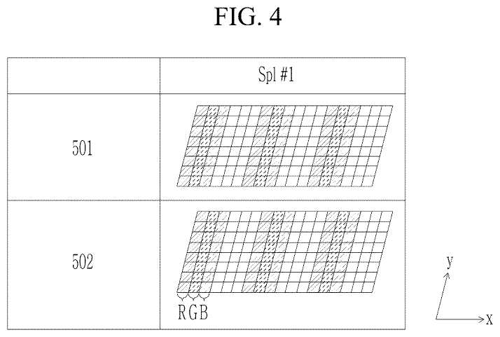

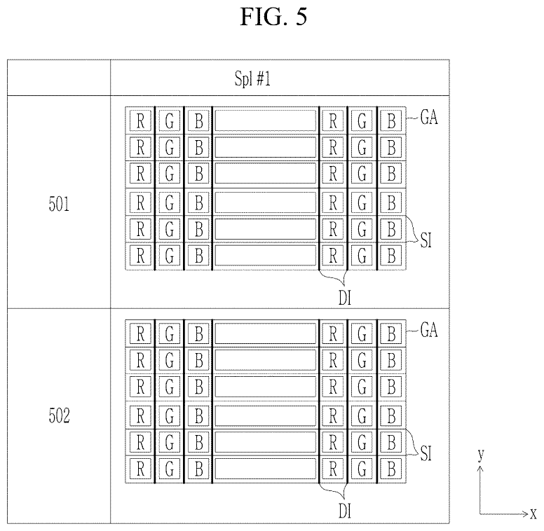

Hereinafter, various embodiments of a pixel arrangement structure of the first display unit 501 and the second display unit 502 will be discussed with reference to FIGS. 4 to 11. FIG. 4 and FIG. 5 are plan views showing an example of a display device.

According to the embodiment of FIG. 4, in the first display unit 501 and the second display unit 502, the first row may have a red pixel row R, the second row a green pixel row G, and the third row a blue pixel row B. These three pixel rows together are referred to as a unit pixel row. At this time, a pixel row is a row of the same color arranged in the y-axis direction. The fourth, fifth, and sixth rows are transmission areas TA where no pixel rows are arranged. Subsequently, starting from the seventh, eighth, and ninth rows, the unit pixel rows are repeated again, and the transmission area TA and the display area PA are alternately arranged. When viewed from the front of the first display unit 501, unit pixel rows in the display area PA of the first display unit 501 and the second display unit 502 may overlap. Thus, in the embodiment of FIGS. 4 and 5, the first display unit 501 and the second display unit 502 have the same unit pixel rows provided with the same arrangement in correspondence with one another.

In FIG. 5, scan lines SI mainly extend in the horizontal direction and transmit a scan signal to corresponding ones of the unit pixels. The data lines DI mainly extend vertically and control corresponding pixels and transmits information.

The structure of the display device according to an embodiment of the present disclosure described above is only an example, and various modifications are possible. In one embodiment, a fourth pixel row other than red, green, and blue may be included in the unit pixel row, any one pixel row may be omitted, or the order of the colors may be changed. Additionally, pixels of the same color may be arranged in the same row in the x-axis direction to form a unit pixel row.

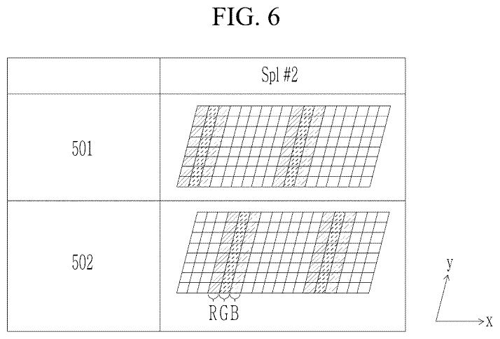

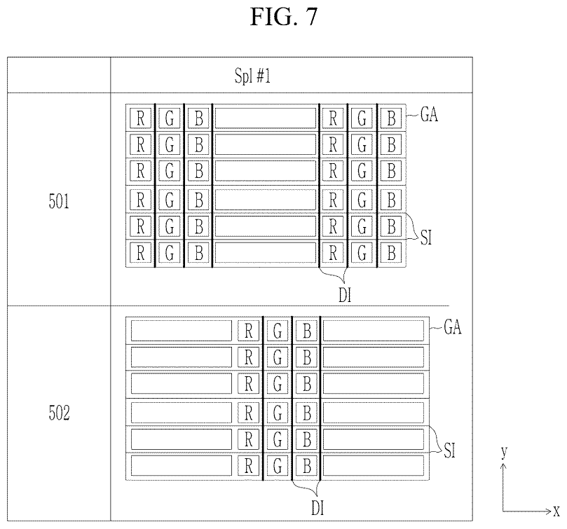

FIG. 6 and FIG. 7 are plan views showing an example of a display device. In this example, the pixel rows in the first display unit 501 are arranged differently from the pixel rows in the second display unit 502.

According to the embodiment in FIG. 6, in the first display unit 501, the first row may have a red pixel row R, the second row a green pixel row G, and the third row a blue pixel row B, and these three rows together are referred to as a unit pixel row. The fourth, fifth, and sixth rows are transmission areas TA where no pixel rows are arranged.

In the second display unit 502, the first, second, and third rows are transmission areas TA where no pixel areas are arranged. In the fourth row there is a red pixel row R, in the fifth row there is a green pixel row G, and in the sixth row there is a blue pixel row B. Thus, the arrangement of pixels in the second display unit 502 may be a shifted version of the 3 pixel rows in the first display unit 501 as viewed along the x-axis. Accordingly, when viewed from the front of the first display unit 501, the positions of unit pixel rows in the display area PA of the first display unit 501 and the second display unit 502 may be different and may not overlap one another.

The structure of the display device according to an embodiment of the present disclosure described above is only an example, and various modifications are possible. For example, a fourth pixel row other than red, green, and blue may be included in the unit pixel row, or any one pixel row may be omitted. Additionally, pixels of the same color may be positioned in the same row to form a unit pixel row arranged in the x-axis direction. Additionally, if the display area PA of the first display unit does not move by the size of a unit pixel row in the second display unit 502, one or more pixel rows of the first display unit 501 may partially overlap one or more pixel rows of the second display unit 502.

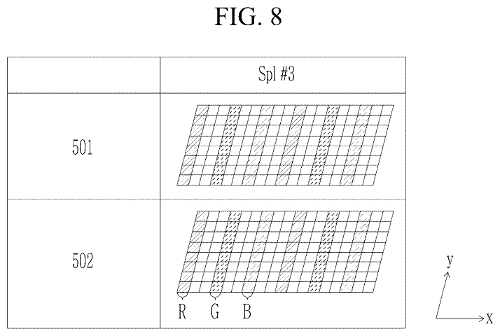

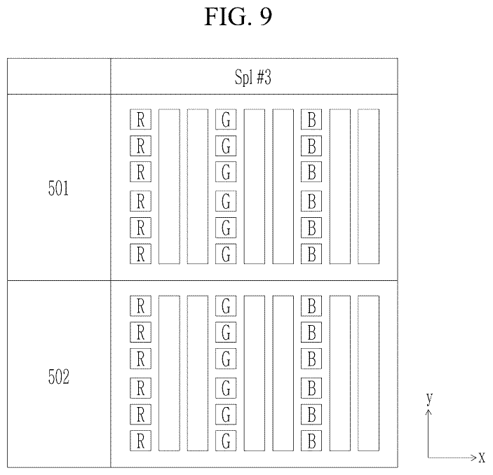

FIG. 8 and FIG. 9 are plan views showing an example of a display device. In this embodiment, one or more transmission areas are provided between adjacent pixel rows of a unit pixel, and the arrangement of pixel rows in the first display unit 501 is the same as the arrangement of pixel rows in the second display unit 502. In FIG. 9, data lines and scan lines are omitted.

According to one embodiment, a red pixel row R is positioned in the first row of the first display unit 501 and the second display unit 502, and no pixel rows are arranged in the transmission area TA in the second and third rows. The green pixel row G is located in the fourth row, and the fifth and sixth rows are transmission areas TA and no pixel rows are arranged. Next, the blue pixel row B is located in the seventh row, and the eighth and ninth rows are transmission areas TA where no pixel row is located.

Thus, when viewed from the front of the first display unit 501, pixel rows in the display area PA of the first display unit 501 and the second display unit 502 may overlap. The present disclosure is not limited to this, and the color and configuration order of the pixel rows may be changed and the size of the transmission area TA between each pixel row may also be changed. For example, only one transmission area (with no pixel rows) may be located between adjacent ones of the red, green, and blue pixel rows, or more than two transmission areas (with no pixel rows) may be located between adjacent ones of the red, green, and blue pixel rows.

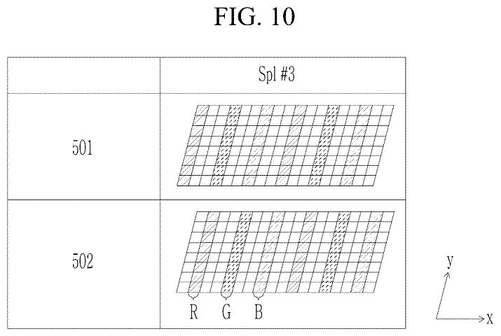

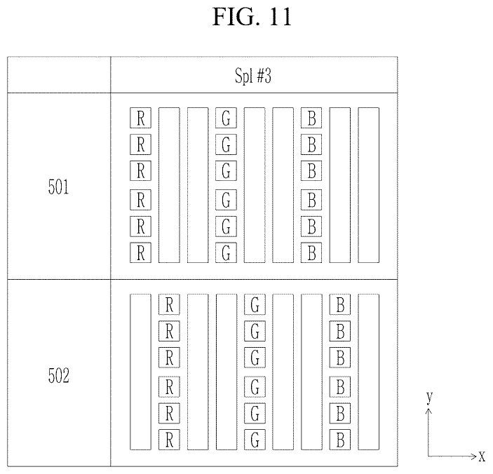

FIG. 10 and FIG. 11 are plan views showing an example of a display device. In this embodiment, the pixel rows in the first display unit 501 are in an offset alternating pattern relative to the pixel rows in the second display unit 502. In FIG. 11, data lines and scan lines are omitted.

According to this embodiment, a red pixel row R is located in the first row of the first display unit 501, and no pixel rows are arranged in the second and third rows in the transmission area TA. The green pixel row G is located in the fourth row, and the fifth and sixth rows are transmission areas TA where no pixel rows are arranged. Next, the blue pixel row B is located in the seventh row, and the eighth and ninth rows are transmission areas TA where no pixel row is located.

In the second display unit 502, the first row is a transmission area TA in which no pixels exist, and the second row contains a red pixel row R. The third and fourth rows are transmission areas TA where no pixels exist, and the fifth row is where the green pixel row G is located. The sixth and seventh rows are transmission areas TA where no pixels exist, and the blue pixel row B is located in the eighth row. Thus, the pixel rows in the second display unit 502 are shifted along the x-axis by one row compared to the pixel rows in first display unit 501.

The present disclosure is not limited to this, and the color and configuration order of the pixel rows may be changed and the size of the transmission area TA between each pixel row may also be changed. Compared to the first display unit 501, the movement size or direction of the pixel row located in the second display unit 502 is not limited to a specific embodiment and may be set in various ways. For example, the pixel rows in the second display unit 502 may be shifted by two or more rows along the x-axis compared to the pixel rows in the first display unit 501.

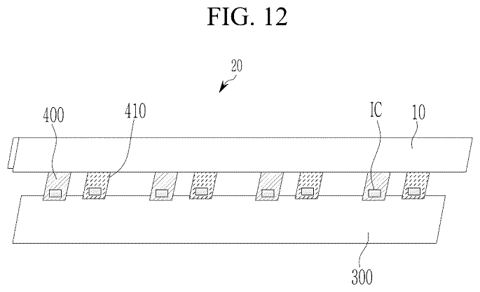

In the following description, various structures are discussed from FIGS. 12 to 17, in which the first display unit 501 and the second display unit 502 located on different sides of the tempered glass plate GA are electrically connected to the printed circuit board 300 via integrated circuit films 400, 410, 401, and/or 411.

FIG. 12 is a perspective view of a display device 20 according to an embodiment. The display device 20 includes display device 10 connected to the printed circuit board 300. As previously indicated, the display device includes the tempered glass plate GA, a first display unit 501, and a second display unit 502. The display device 20 further includes a first integrated circuit film 400 located on (or coupled to) the first display unit, a second integrated circuit film 410 located on (or coupled to) the second display unit, and a driver chip IC, as well as printed circuit board 300.

The integrated circuit films 400 and 410 may include, for example, a base film, a driver chip IC, conductive wires, and via patterns. The first display unit 501 and the second display unit 502, which are placed on opposing sides of the tempered glass plate GA of the display device 20, may be connected to the printed circuit board 300 by utilizing the chip-on-film COF technology of the integrated circuit films 400 and 410.

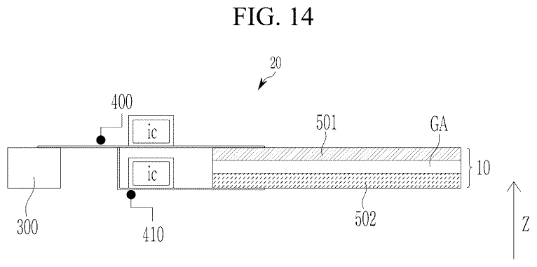

In this structure, the first integrated circuit film 400 and the second integrated circuit film 410 are electrically connected to a pad area located on one side (also referred to as the first side) of the printed circuit board 300, and have a structure that connects to the same side of the printed circuit board 300. Additionally, the control drive chip may be formed on the printed circuit board 300. The control drive chip on the printed circuit board 300 may transmit and control data signals to each drive chip IC on the integrated circuit films 400 and 410. FIG. 14 shows this connection structure in greater detail.

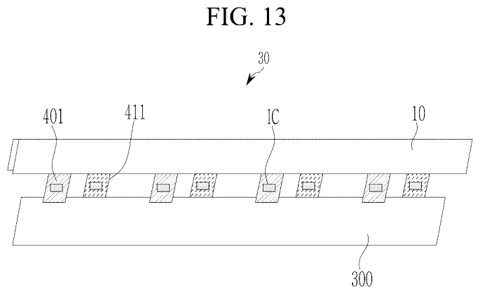

FIG. 13 is a perspective view of a display device 30 according to another embodiment. Except for the connection method, display device 30 is the same as the display device according to FIG. 12 described above. In this embodiment, a first integrated circuit film 401 is connected to the first side of the printed circuit board 300, and a second integrated circuit film 411 is located on the second side, which is the opposite side of the first side, and may be connected to respective sides of the printed circuit board 300. In this structure, the first integrated circuit film 401 and the second integrated circuit film 411 are electrically connected to pad parts located on the first side of the printed circuit board 300 and pad parts located on the second side, which is opposite to the first side, forming a structure that connects to both sides of the printed circuit board 300.

FIG. 14 is a cross-sectional view of one embodiment of FIG. 12. The display device 20 includes the tempered glass plate GA, the first display unit 501, the second display unit 502, a first integrated circuit film 400 located on the first display unit 501, a second integrated circuit film 410 located on the second display unit 502, at least one driver chip IC, and a printed circuit board 300. The printed circuit board 300 is electrically connected to the first display unit 501 and the second display unit 502 formed on opposing sides of the tempered glass plate GA through respective ones of the integrated circuit films 400 and 410.

On the first side of the printed circuit board 300, a first a pad part and a first b pad part, which are alternately arranged, are formed, the first integrated circuit film 400 is connected to the first a pad part of the printed circuit board 300, and the second integrated circuit film 410 may be connected to the first b pad part of the printed circuit board 300. Meanwhile, a second a pad part and a second b pad part are formed on the first and second sides of the tempered glass plate GA, respectively, the first integrated circuit film 400 is connected to the second a pad part of the tempered glass plate GA, and the second integrated circuit film 410 may be connected to the second b pad part of the tempered glass plate GA.

Each of the first integrated circuit film 400 and the second integrated circuit film 410 are formed with conductive wires, so that the printed circuit board 300, the first display unit 501, and the second display unit 502 are electrically connected to each other. At this time, the conductive wire(s) located in the first integrated circuit film 400 and the conductive wire(s) in the second integrated circuit film 410 may be connected, and depending on the embodiment, may have a structure in which they are separated from each other.

In FIG. 14, the at least one driver IC includes two driver ICs coupled to respective ones of the first integrated circuit film 400 and the second integrated circuit film 410. A control driver chip may be located on the printed circuit board 300. In some cases, there may be more driver chips than those described in one embodiment. Two display units may be efficiently driven through the driver chip ICs. The driver chips IC play a role in controlling the pixels of the display unit. By using multiple driver chips ICs, stable driving of a high-resolution or large-sized display may be possible.

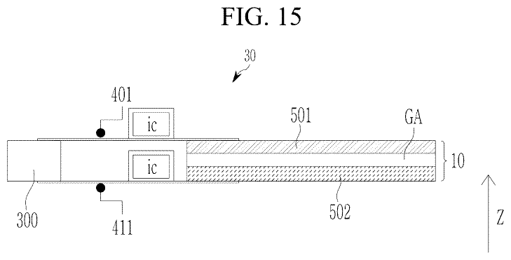

FIG. 15 is a cross-sectional view of the display device 30 of FIG. 13.

The display device 30 includes the tempered glass plate GA, the first display unit 501, the first integrated circuit film 401 connecting the first display unit 501 and the printed circuit board 300, the second display unit 502, and the second integrated circuit film 411 connecting the second display unit 502 and the printed circuit board 300. The printed circuit board 300 is electrically connected to the first display unit 501 and the second display unit 502 formed on opposing sides of the tempered glass plate GA through integrated circuit films 401 and 411.

On the first side of the printed circuit board 300, a first pad part is formed, and on the second side, a second pad part is formed, the first integrated circuit film 401 is connected to the first pad part of the printed circuit board 300, and the second integrated circuit film 411 may be connected to the second pad part of the printed circuit board 300. Meanwhile, a second pad part a and a second pad part b are formed on the first and second sides of the tempered glass plate GA, respectively. The first integrated circuit film 400 is connected to the second pad part of the tempered glass plate GA, and the second integrated circuit film 410 may be connected to the second pad part of the tempered glass plate GA.

Each of the first integrated circuit film 401 and the second integrated circuit film 411 are formed with conductive wires, so that the printed circuit board 300, the first display unit 501, and the second display unit 502 are electrically connected to each other.

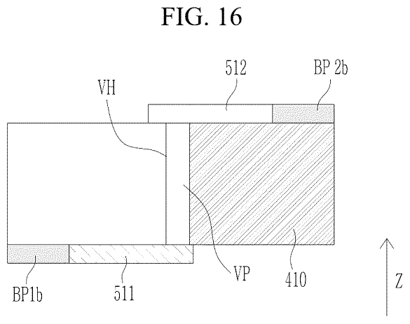

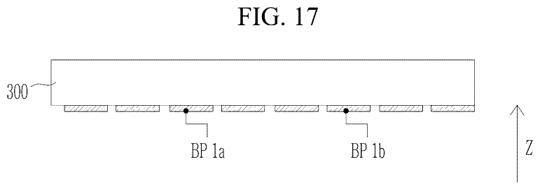

The driver chip ICs may be located on the first integrated circuit film 401 and the second integrated circuit film 411. A control driver chip may also be located on the printed circuit board 300. In some cases, there may be more driver chips than those described in one embodiment. Hereinafter, the electrical connection structures of FIGS. 12 and 14 will be discussed in more detail with reference to FIGS. 16 and 17.

FIG. 16 is a cross-sectional view of the second integrated circuit film 410 of FIG. 12 or FIG. 14 according to one embodiment.

In FIG. 16, a first wiring 511 and a first b pad part BP 1b are formed on one side of the second integrated circuit film 410, and second wiring 512 and a second b pad part BP 2b are formed on the other side. The first conductive wire 511 may be an extension of the 1b pad portion BP 1b, and the second conductive wire 512 may be an extension of the 2b pad portion BP 2b. A via hole VH penetrating the second integrated circuit film 410 may be formed in an area where the first conductive wire 511 and the second conductive wire 512 overlap. A via pattern VP is provided within the via hole VH. The via pattern VP may penetrate the second integrated circuit film 410 to electrically connect the first conductor 511 and the second conductor 512.

According to the structure of the second integrated circuit film 410 of FIG. 16, the 1b pad part BP 1b may be located on the same first side of the printed circuit board 300 as the 1a pad part BP 1a. Through this, as in the examples of FIGS. 12 and 14, the first pad part BP 1a and the second pad part BP 1b located on the first side of the printed circuit board 300 may be electrically connected to the first display portion 501 and the second display portion 502, respectively.

FIG. 17 is a cross-sectional view of the printed circuit board 300 of FIG. 14.

The printed circuit board 300 includes a first pad part BP 1a of the printed circuit board 300, which is connected to the first integrated circuit film 400, and a first pad part BP 1b of the printed circuit board 300, which is connected to the second integrated circuit film 410. The 1a pad portion BP 1a and the 1b pad portion BP 1b may be alternately positioned on one side (also referred to as the first side) of the printed circuit board 300. However, depending on the embodiment, the 1a pad part BP 1a and the 1b pad part BP 2b may be located overlapping on the first side, or may be formed on the first side and the second side and thus located on different sides.

A display device according to an embodiment may be applied to various electronic devices. An electronic device according to an embodiment may include the display device, and may further include modules or devices having additional functions other than the display device.

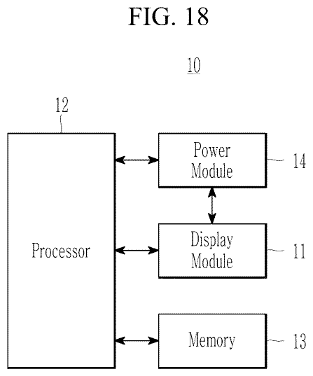

FIG. 18 is a block diagram of an electronic device according to an embodiment. Referring to FIG. 18, the electronic device 1000 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for operations of the processor 12 or the display module 11. When the processor 12 executes an application stored in the memory 15, video data signals and/or input control signals are transmitted to the display module 11, and the display module 11 can process the received signals to output video information through the display screen.

The power module 14 may include a power supply module such as a power adapter or battery device, and a power conversion module that converts the power supplied by the power supply module to generate the power necessary for the operation of the electronic device 1000.

At least one of components of the electronic device 1000 may be included within the display device according to the above-described embodiments. Additionally, some of the individual modules that are functionally included within a single module may be incorporated into the display device, while others may be provided separately from the display device. For example, the display device may include the display module 11, while the processor 12, memory 13, and power module 14 may be provided in a form of other devices within the electronic device 1000 that are not part of the display device.

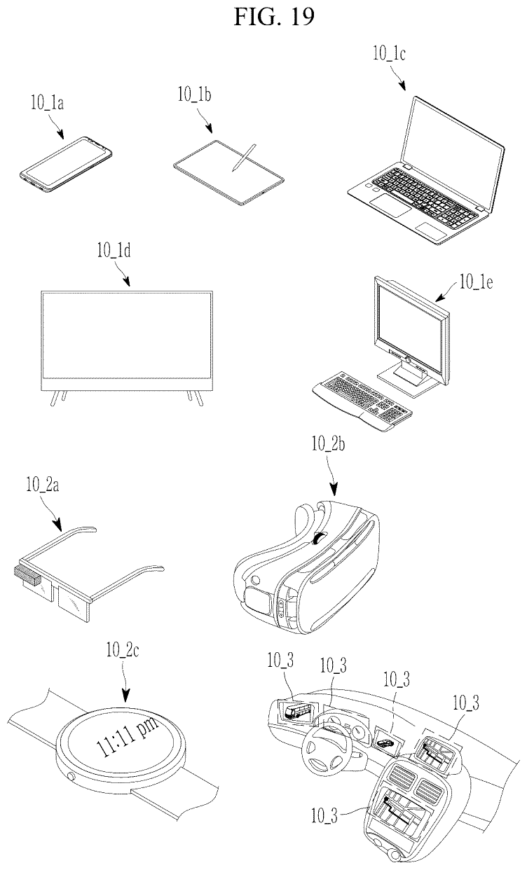

FIG. 19 shows schematic diagrams of electronic devices according to various embodiments.

Referring to FIG. 19, various electronic devices with the display device according to the embodiments may include not only image display electronic devices such as smartphones 1000_1a, tablet PCs 1000_1b, laptops 1000_1c, TVs 1000_1d, desktop monitors 1000_1e, but also wearable electronic devices with display modules such as smart glasses 1000_2a, head-mounted displays 1000_2b, smart watches 1000_2c, as well as automotive electronic devices with display modules 1000_3 such as those placed on car dashboards, center fascias, CID (Center Information Display), room mirror displays, and so on.

Although the embodiments of the present disclosure have been described in detail above, the scope of the present disclosure is not limited thereto, and various modifications and improvements made by those skilled in the art using the basic concepts of the present disclosure defined in the following claims are also possible. The embodiments may be combined to form additional embodiments.

What is claimed is:

1. A display device, comprising:
a tempered glass plate;
a first display located on a first side of the tempered glass plate and having a first display area and a first transmission area arranged in one direction, the display area including a first pixel circuit layer and a first light emitting element layer; and
a second display located on a second side of the tempered glass plate in an opposite direction to the first side which the first display is located on, the second display having a second display area including a second pixel circuit layer and a second light emitting element layer and a second transmission area arranged in the one direction.

2. The display device of claim 1, wherein:
each of the first display area of the first display and the second display area of the second display includes a unit pixel row including one red, one green, and one blue color, and
when viewed from a front of the first display, the first display area of the first display unit and unit pixel rows of the second display area of the second display overlap.

3. The display device of claim 1, wherein:
each of the first display area of the first display and the second display area of the second display include a unit pixel row including one red, one green, and one blue color, and
unit pixel rows of the first display area of the first display and the second display area of the second display do not overlap when viewed from a front of the first display.

4. The display device of claim 1, wherein:
in the first display area of the first display and the second display area of the second display, the first and second transmission areas are located between adjacent pixel rows displaying light of different colors, and
the pixel rows of the first display area of the first display and the pixel rows of the second display area of the second display overlap when viewed from a front of the first display.

5. The display device of claim 1, wherein:
in the first display area of the first display and the second display area of the second display, the first and second transmission areas are located between adjacent pixel rows that display light of different colors, and
pixel rows of the first display area of the first display and the second display area of the second display do not overlap when viewed from the front of the first display.

6. The display device of claim 1, wherein each of the first light emitting element layer and the second light emitting element layer includes a blue light emitting layer.

7. The display device of claim 1, wherein:
the first display includes a first thin film encapsulation layer on the first light emitting element layer of the first display, and
the second display includes a second thin film encapsulation layer below the second light emitting element layer of the second display.

8. The display device of claim 7, wherein each of the first thin film encapsulation layer and the second thin film encapsulation layer includes a triple layer in which an inorganic film, an organic film, and an inorganic film are sequentially formed.

9. The display device of claim 7, wherein:
the first display includes a first color conversion layer on the first thin film encapsulation layer of the first display, and
the second display includes a second color conversion layer below the second thin film encapsulation layer of the second display.

10. The display device of claim 9, wherein each of the first color conversion layer and the second color conversion layer includes quantum dots (QD).

11. The display device of claim 9, wherein:
the first display includes a first color filter layer on an upper portion of the first color conversion layer of the first display, and
the second display includes a second color filter layer below the second color conversion layer of the second display.

12. The display device of claim 11, wherein:
the first display includes a first cover glass substrate on the first color filter layer of the first display, and
the second display includes a second cover glass substrate below the second color filter layer of the second display.

13. The display device of claim 12, wherein:
the first display includes a first anti-reflection film on the first cover glass substrate of the first display, and
the second display includes a second anti-reflection film below the second cover glass substrate of the second display.

14. The display device of claim 11, wherein:
the first display includes a first overcoat layer on the first color filter layer of the first display, and
the second display includes a second overcoat layer below the second color filter layer of the second display.

15. The display device of claim 1, wherein each of the first pixel circuit layer and the second pixel circuit layer includes an oxide thin film transistor.

16. The display device of claim 15, wherein the semiconductor layer of the oxide thin film transistor includes any one of ITO, poly-ITO, IZO, IGZO, or ITZO.

17. A display device, comprising:
a first display and a second display located on opposing sides of a tempered glass plate, respectively;
a printed circuit board;
a first integrated circuit film connecting the first display and the printed circuit board;
a second integrated circuit film connecting the second display and the printed circuit board; and
driver chips formed on respective ones of the first integrated circuit film and the second integrated circuit film, wherein the first integrated circuit film is connected to a first side of the printed circuit board, and the second integrated circuit film is connected to a second side of the printed circuit board.

18. The display device of claim 17, wherein the first side and the second side are the same side of the printed circuit board.

19. The display device of claim 18, wherein the second integrated circuit film includes a via hole penetrating the second integrated circuit film and a via pattern formed in the via hole.

20. The display device of claim 17, wherein the second side is an opposing side of the printed circuit board.

21. An electronic device comprising:
a memory;
a processor executing an application stored in the memory; and
a display device comprising a display module outputting video information provided by the application, wherein
the display device comprising:
a tempered glass plate;
a first display located on a first side of the tempered glass plate and having a first display area and a first transmission area arranged in one direction, the display area including a first pixel circuit layer and a first light emitting element layer; and
a second display located on a second side of the tempered glass plate in an opposite direction to the first side which the first display is located on, the second display having a second display area including a second pixel circuit layer and a second light emitting element layer and a second transmission area arranged in the one direction.
